(19) United States
(12) Patent Application Publication
(10) Pub. No.: US 2003/0213436 A1
(43) Pub. Date: Nov. 20, 2003

(54) Batch type atomic layer deposition apparatus

(76) Inventor: Hyung-Jin Kwon, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 10/331,729

(22) Filed: Dec. 31, 2002

(30) Foreign Application Priority Data
May 18, 2002 (KR) 2002-27614

(51) Int. Cl. C23C 16/00

(52) U.S. Cl. 118/725; 118/730

(57) ABSTRACT

Provided is an atomic layer deposition apparatus that can prevent the degradation of a sheet resistance uniformity as well as enhance the throughput. The atomic layer deposition apparatus of this research includes: a rotary plate in the chamber, wherein a plurality of wafers positioned on the rotary plate to equal distances from the center of the rotary plate; a gas injecting means confronting the upper surface of the rotary plate at the center; and a heating plate cable of controlling the temperature of the wafers according to the location, wherein the heating plate is mounted on the bottom plate and a space is provided between the heating plate and the bottom surface of the rotary plate.

### FIELD OF THE INVENTION

The present invention relates to an atomic layer deposition (ALD) apparatus; and, mote particularly, to a batch type apparatus for depositing an atomic layer

### DESCRIPTION OF RELATED ART

Generally, when a semiconductor device is fabricated, a sputtering, chemical vapor deposition (CVD), or atomic layer deposition (ALD) method is used to deposit a thin film uniformly.

First, sputtering is a method flowing an inert gas such as argon (Ar) into a vacuum chamber while supplying high voltage to a target so as to generate Ar ions in the plasma state. At this time, the Ar ions are sputtered on the surfaces of the target, and the atoms of the target are removed from the surfaces of the target. The sputtering method can form a highly pure thin film having an excellent adhesive property to a substrate. However, when a highly integrated thin film, which is fabricated differently from a common thin film, is deposited in the sputtering method, the surface of the entire thin film becomes uneven. Therefore, the sputtering method has a problem in depositing a fine pattern.

Secondly, CVD is the most widely used method. It deposits a thin film on a substrate in a required thickness by using reaction gases and resolving gases. For example, in the CVD method, various gases are flown into a reaction chamber first, and then the gases are arranged to perform chemical reactions with a high energy, such as heat, light, and plasma to deposit a thin film in a required thickness.

In addition, in the CVD method, the deposition rate is increased by controlling the reaction conditions, such as the amount and ratio of the gases or the plasma supplied as much as the reaction energy.

However, since the reactions are performed rapidly, it is very hard to control the thermodynamic stability of the atoms. Conclusively, the CVD method deteriorates the physical and chemical electricity properties of a thin film.

Lastly, ALD is a method for depositing an atom-based thin film by supplying a source gas (i.e., reaction gas) and a purge gas, alternately. A thin film formed by performing ALD is uniform at a low pressure, and it has high aspect ratio and excellent electrical and physical properties.

Since the CVD method has a shortcoming that the step coverage is limited especially for a structure having a very large aspect ratio, the ALD method using a surface reaction is used to overcome the limit of step coverage, recently.

FIG. 1A is a schematic diagram showing a traveling wave-type ALD apparatus according to prior art, and FIG. 1B is a timing diagram of an ALD deposition using the apparatus of FIG. 1A. FIG. 1C is a flow chart describing an ALD process of the apparatus shown in FIG. 1B.

Referring to FIG. 1A, the traveling wave-type chamber 10 is formed in the shape of a tunnel. The chamber 10 includes a long wafer 11 which is inserted to the camber 10 in the longitudinal direction and positioned at the bottom of the chamber 10; gas injection passages 12A and 12B which are formed in one side of the chamber 10, for flowing gases, such as a source gas, a reaction gas and a purge gas; and a pump 13 formed in the another side of the chamber 10, for discharging the gases.

The traveling wave-type ALD apparatus described above deposits an atomic layer as shown in FIG. 1C according to the timing diagram illustrated in FIG. 1B.

In the period T₁, the wafer 11 is loaded in the chamber 10, and then a source gas (A) is injected into the chamber 10 to be chemical-adsorbed into the wafer 11. In the period T₂, the remaining source gas (A) is discharged out by flowing a purge gas, such as an inert gas. In the period T₃, an atomic layer (C) is deposited by flowing in a reaction gas (B) and inducing a surface reaction between the source gas (A) chemically adsorbed on the wafer 11 and the reaction gas (B). In the period T₄, the remaining reaction gas (B) and other reaction by-products are discharged out by flowing a purge gas, such as an inert gas, again. The periods T₁ to T₄ are performed repeatedly, until an atomic layer is deposited in a desired thickness, the periods T₁ to T₄ being a cycle.

The above-described conventional technology can produce a conformal and uniform thin film. It can also suppress the generation of particles, which is caused by performing a gas phase reaction, more successively than the CVD method, because the source and reaction gases are separated by the inert gas before they are supplied to the chamber. In addition, it can improve the utility efficiency of the source gas and reduce the cycle time by inducing multiple collisions between the source gas atoms and the wafer atoms.

However, the above-described conventional technology has a problem of poor throughput as low as 3˜4 WPH (Wafer Per Hours). So, it needs a lot of mechanical devices and high maintenance cost.

Also, as shown in FIG. 2, the traveling wave-type atomic layer deposition apparatus controls the temperature of the reaction zone uniformly by using the top heater 14A and the bottom heater 14B. Therefore, there is a problem that the atomic layer 15 is deposited not only on a bottom plate 10B provided with the wafer 11 where the atomic layer is deposited substantially, but also on a top plate 10A as well.

Furthermore, since the ALD apparatus is a traveling wave-type, the rear end (i.e., the part where the gases stop flowing) of the heating zone, where the atomic layer should be deposited, has more gases remaining after reactions and generates more reaction by-products 16 than the fore end of the heating zone. The remaining gases and the by-products are highly likely to be re-deposited on the wafer at the rear end of the heating zone.

After all, the non-resistance characteristic of the atomic layer is deteriorated due to the uniform temperature and the re-deposition, followed by such a constraint that the wafer should be rotated at 90 to improve the thickness and the sheet resistance (Rs) uniformity, in the atomic layer deposition cycle. This constraint goes against the mass production of semiconductor devices.

### SUMMARY OF THE INVENTION

It is, therefore, an object of the present invention to provide an atomic layer deposition apparatus that can improve the throughput and suppress the deterioration of the sheet resistance uniformity.

In accordance with an aspect of the present invention, there is provided an apparatus for depositing an atomic layer, comprising: a chamber having a top plate, a bottom plate and a side wall; a rotary plate in the chamber, wherein a plurality of wafers positioned on the rotary plate to equal distances from the center of the rotary plate; a gas injecting means confronting the upper surface of the rotary plate at the center; and a heating plate cable of controlling the temperature of the wafers according to the location, wherein the heating plate is mounted on the bottom plate and a space is provided between the heating plate and the bottom surface of the rotary plate.

### BRIEF DESCRIPTION OF THE DRAWINGS

The above and other objects and features of the present invention will become apparent from the following description of the preferred embodiments given in conjunction with the accompanying drawings, in which:

FIG. 1A is a schematic diagram showing a traveling wave-type atomic layer deposition (ALD) apparatus according to prior art;

FIG. 1B is a timing diagram of an ALD deposition using the apparatus of FIG. 1A;

FIG. 1C is a flow chart describing an ALD process of the apparatus shown in FIG. 1B;

FIG. 2 is a schematic diagram showing the problem of the prior art;

FIG. 3 is a diagram illustrating a batch type apparatus for depositing an atomic layer in accordance with a first embodiment of the present invention;

FIG. 4A is a detailed cross-sectional view showing a heating plate illustrated in FIG. 3;

FIG. 4B is a detailed plane figure showing a heating plate illustrated in FIG. 3;

FIG. 5 is a map illustrating the sheet resistance uniformity after TiN is deposited using the reaction chamber of FIG. 3;

FIG. 6 is a diagram showing a batch type apparatus for depositing an atomic layer in accordance with a second embodiment of the present invention;

FIG. 7 is a diagram showing the deposition status of an atomic layer, when it is deposited using the ALD apparatus of FIG. 6; and

FIG. 8 is a map illustrating the sheet resistance uniformity after TiN is deposited using the reaction chamber of FIG. 6.

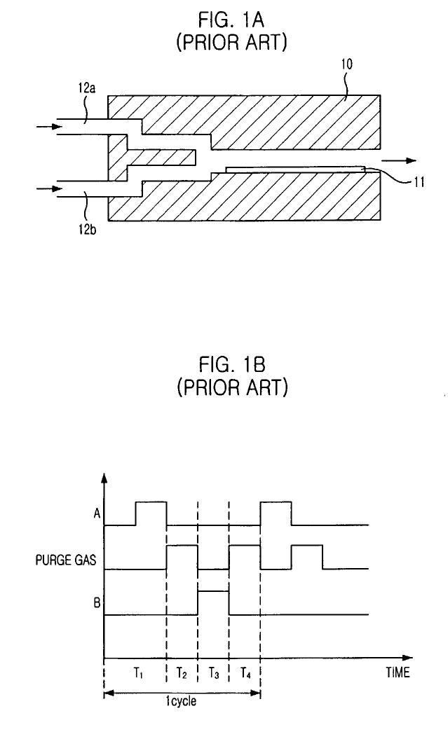

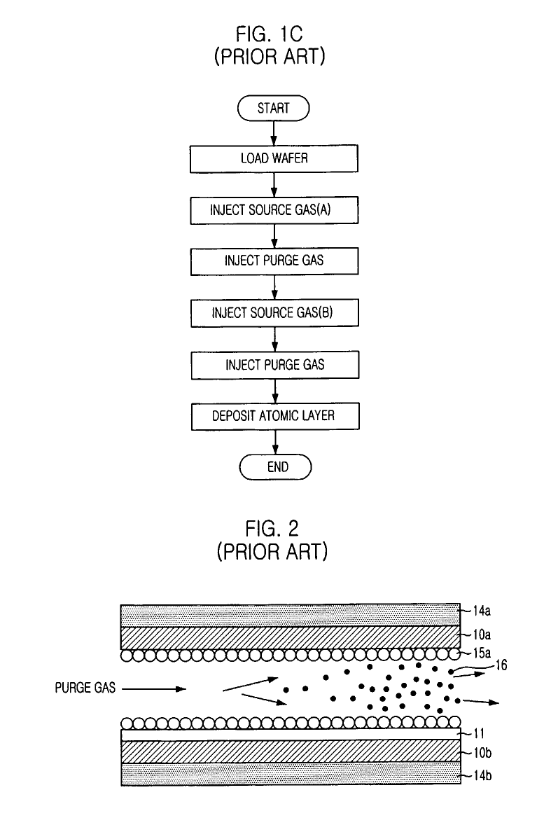

### DETAILED DESCRIPTION OF THE INVENTION

Other objects and aspects of the invention will become apparent from the following description of the embodiments with reference to the accompanying drawings, which is set forth hereinafter.

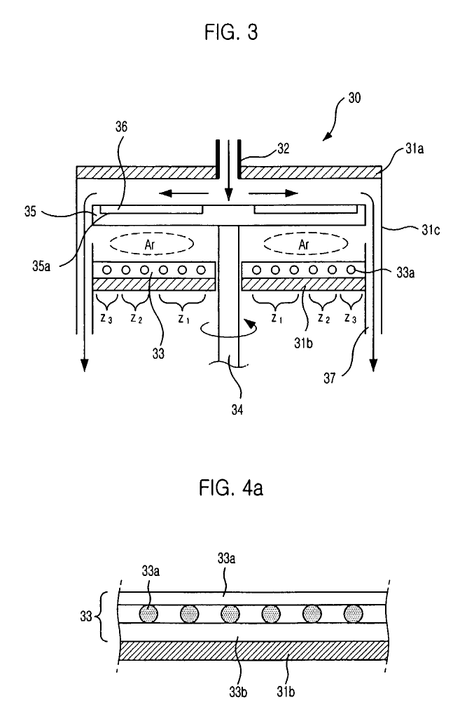

FIG. 3 is a diagram illustrating a batch type apparatus for depositing an atomic layer in accordance with a first embodiment of the present invention. As illustrated in FIG. 3, the batch type atomic layer deposition (ALD) apparatus includes: a reaction chamber 30 having a side wall 31c, a top plate 31a and a bottom plate 31b; a hole-type showerhead 32 for injecting gases, such as source, reaction, and purge gases, through the center of the top plate 31a of the reaction chamber 30; a heating plate 33 which is mounted on the bottom plate 31b thereby providing a space between the bottom plate 31b and the bottom surface of the rotary plate 35, and cable of controlling the temperature of the wafers according to the location; a rotary shaft 34 penetrating the center of the bottom plate 31b and the heating plate 33; a rotary plate 35 on which a plurality of wafers 36 are positioned to an equal distances from the center of the rotary plate 35, wherein the rotary plate is supported by the rotary shaft 34 connected to the center of the bottom surface of the rotary plate; and a baffle-type discharging outlet 37 for discharging the gases injected from the hole-type showerhead 32 to the outside, the discharging outlet 37 penetrates the bottom plate 31b along the side wall 31c.

The heating plate 33 is divided into three heating zones confronting to each other from the center. In each heating zones, ARC lamps 33a are arrayed in the form of a loop at a predetermined interval from each other. The wafer heating zone for atomic layer deposition (ALD) is divided into three: Z₁, Z₂ and Z₃.

The heating plate 33 is placed right under the rotary plate 35. The first heating zone Z₁, which is the closest to the showerhead 32 among the three heating zones, is formed of three ARC lamps 33a, and the third heating zone Z₃, aligned to the outskirts of the rotary plate 35 is formed of one ARC lamp 33a. The second heating zone Z₂ between the first heating zone Z₁ and the third heating zone Z₃ is formed of two ARC lamps 33a.

Therefore, the temperature of each heating zone can be controlled differently by controlling the power rate of the ARC lamp 33a. For example, based on the ARC lamp power rate of the second heating zone Z₂, the ARC lamp power rate of the first heating zone Z₁ can be heightened, and the lamp power rate of the third heating zone Z₃ can be lowered. To the contrary, the ARC lamp power rate of the first heating zone Z₁ can be lowered, and the lamp power rate of the third heating zone Z₃ can be heightened. Meanwhile, the ARC lamp power rate is a parameter that determines the temperature of a wafer on which an atomic layer is to be deposited. The ARC lamp is set at a temperature as high as to heat up the wafer and deposit an atomic layer.

The rotary plate 35 is provided with a wafer groove 35a on its upper surface for placing the wafer 36. The wafer groove prevents the atomic layer from being deposited on the bottom surface of the-wafer 36 and protects the wafer 36 from being shaken when the rotary plate 35 is rotated.

In the ALD apparatus having the above-described structure, the source, reaction and purge gases are supplied through the central part (i.e., a hole-type showerhead) of the top plate 31a. The supplied gases form a traveling wave-type of a flow towards the outside of the rotary plate 35, and then they are pumped into the outside of the reaction chamber 30 through the discharging outlet 37 in the outside of the rotary plate 35.

The rotary plate 35 is rotated to secure a deposition uniformity and to place the wafer. Under the rotary plate 35, an inert gas, such as Ar, is flowing to prevent an atomic layer from being deposited on the bottom surface of the rotary plate 35. The inert gas flowing under the rotary plate 35 is supplied from outside through an additional gas injection passage (not shown).

As described above, in the first embodiment of the present invention, gases are supplied from the central part of the reaction chamber 30 through the showerhead 32, and a plurality of wafers 36 are mounted on the rotary plate 35. The sheet resistance uniformity can be secured by separating the heating zone into three, Z₁, Z₂ and Z₃, and controlling the temperature of the wafer 36, on which the atomic layer is deposited

Meanwhile, the heating plate 33 having an array of loop-type ARC lamps 33a controls the heating power rate of each heating zone to have different temperatures, instead of maintaining a uniform temperature all around the entire region of the wafer 36.

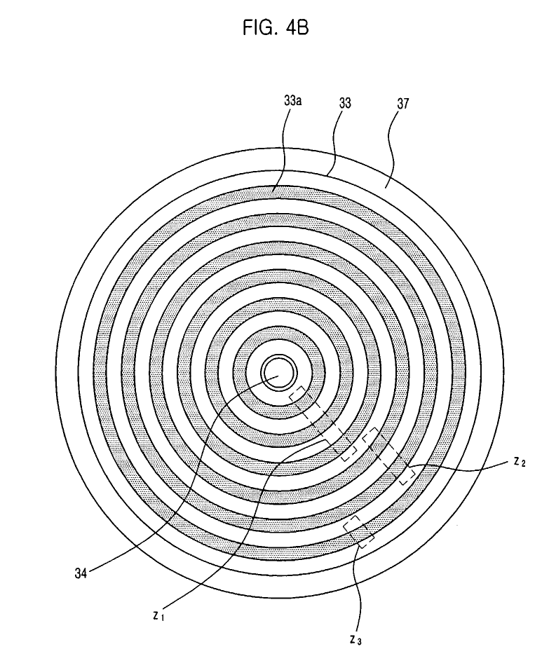

FIG. 4A is a detailed cross-sectional view showing a heating plate illustrated in FIG. 3., and FIG. 4B is a detailed plane figure showing a heating plate illustrated in FIG. 3. Referring to FIGS. 4A and 4B, the heating plate 33 includes an insulator 33b formed on the bottom plate 31b of the reaction chamber, an ARC lamp. 33a formed on the insulator 33b, and quartz 33c covering the ARC lamp 33a. Here, the ARC lamp 33a is a lamp that uses the luminescence of the arc, such as tungsten, which is generated when an electric current flows between electrodes.

As shown in FIG. 4B, the ARC lamp 33a neighboring the rotary shaft 34 forms the first heating zone Z₁, and the ARC lamp 33a neighboring the discharging outlet 37 forms the third heating zone Z₃. The ARC lamp 33a between the first heating zone Z₁ and the third heating zone Z₃ forms the second heating zone Z₂. The temperature of the second heating zone Z₂ becomes the reference temperature for setting the temperature of the heating plate 33.

FIG. 4B shows the first heating zone Z₁ having an array of three ARC lamps, the second heating zone Z₂, having an array of two ARC lamps, and the third heating zone Z₃, having one ARC lamp. This is to control the temperatures of the heating zones differently from each other.

As described above, when only one ARC lamp is placed in the third heating zone Z₃ neighboring the discharging outlet, the injected gas becomes to have a traveling wave-type flow so the remaining gas and other reaction by-products are less likely to be re-deposited on the end of the heating zone (i.e., the third heating zone).

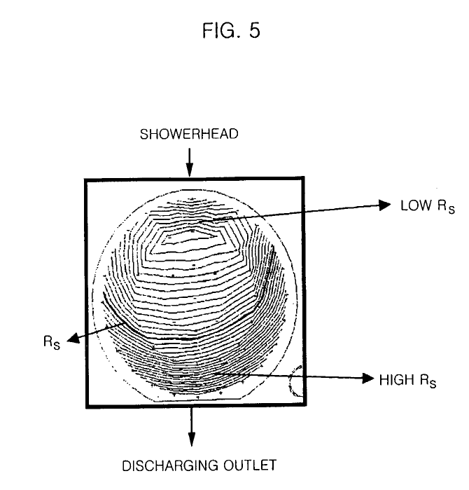

FIG. 5 is a map illustrating the sheet resistance uniformity after TiN is deposited using the reaction chamber of FIG. 3. To obtain the result of FIG. 5, 50 sccm of TiCl₄, a source gas, is flown into the reaction chamber for 0.1.2 seconds under the chamber pressure of 3 torr. Then, 1200 sccm of NH₃, a reaction gas, is flown thereto for 1.2 seconds, and 800 sccm of Ar, a purge gas, is flown for 1.2 seconds. On the bottom surface of the rotary plate, 3000 sccm of Ar is flown for 1.2 seconds. The space between the showerhead and the rotary plate is 3.5 mm and the rotary plate is rotated at a speed of 5 rpm. The heating unit is set at 480 C. The temperature of the wafer is maintained at 480 C by setting the ARC lamp power rate of the first heating zone Z₁ at 62%, the ARC lamp power rate of the second heating zone Z₂ at 65%, and the ARC lamp power rate of the third heating zone Z₃ at 85%. When TiN is deposited under the above process conditions, the average sheet resistance is 72.6 7.51 ▾/sq, and the uniformity is measured to be 10.3%(1▾)

Referring to FIG. 5, the Cl content in a TiN layer appears different in the part close to the discharging outlet and the part close to the showerhead. That is, in a portion of TiN layer corresponding to the central part of the rotary plate 35, Cl is less contained, so the sheet resistance appears low. On the other hand, in a portion of the TiN layer corresponding to the outskirt part of the rotary plate 35 contains a lot of Cl, so the sheet resistance appears high.

Therefore, to control the amount of Cl in the TiN layer uniformly, Cl should be purged efficiently through the purging process by using Ar, or removing the re-deposited Cl by performing heating depending on heating zones.

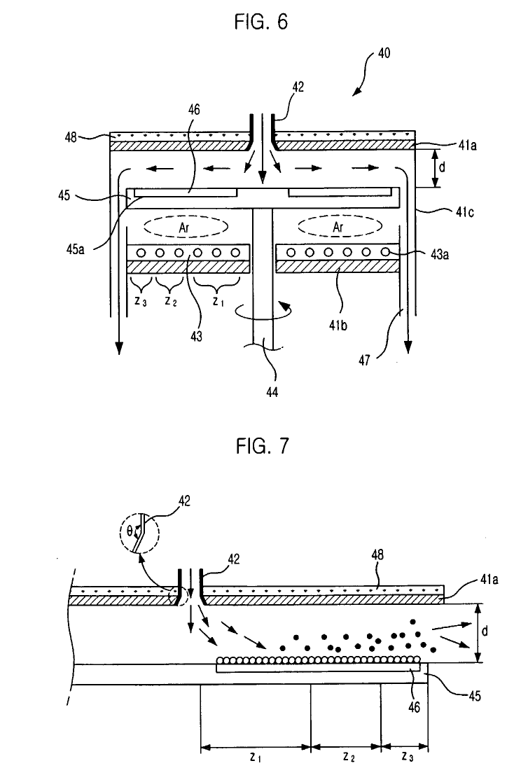

FIG. 6 is a diagram showing a batch type apparatus for depositing an atomic layer in accordance with a second embodiment of the present invention. In the drawing, the atomic layer deposition apparatus includes: a reaction chamber 40 having a side wall 41c, a top plate 41a and a bottom plate 41b; a cone-shaped showerhead 42 for injecting gases, such as source, reaction and purge gases, through the center of the top plate 41a of the reaction chamber 40; a heating plate 43 which is mounted on the bottom plate 41b; a rotary shaft 44 which penetrates the bottom plate 41b and the heating plate 43 at the center simultaneously; a rotary plate 45 having a plurality of wafers 46 and the rotary shaft 44 fixed on the bottom surface of the rotary plate 35 at the center; a baffle-type discharging outlet 47 which penetrates the bottom plate 41b along the side wall 41c neighboring the outskirts of the rotary plate 45 and discharges the gases injected from the cone-shaped showerhead 42 to the outside; and a cooling plate 48 mounted on the top plate 41a.

The cone-shaped showerhead 42 has an enhanced film deposition uniformity, compared to the hole-type showerhead, and the top plate 41a is protected from a layer deposition by placing the cooling plate 48 on the top plate 41a.

Just as the first embodiment, the heating plate 43 is divided into three wafer heating zones to perform ALD: Z₁, Z₂ and Z₃. Each of the heating zones has an array of loop-type ARC lamps 43a at a predetermined interval from each other.

The heating plate 43 is placed right under the rotary plate 45. The first heating zone Z₁ closest to the cone-shaped showerhead 42 among the three heating zones is formed of three ARC lamps 43a, and the third heating zone Z₃ closest to the outskirts of the rotary plate 45 is formed of one ARC lamp 43a. The second heating zone Z₂ between the first heating zone Z₁ and the third heating zone Z₃ is formed of two ARC lamps 43a.

Therefore, the temperature of each heating zone can be controlled differently by controlling the power rate of the ARC lamps 43a. For example, based on the ARC lamp power rate of the second heating zone Z₂, the ARC lamp power rate of the first heating zone Z₁ can be heightened, and the lamp power rate of the third heating zone Z₃ can be lowered. To the contrary, the ARC lamp power rate of the first heating zone Z₁ is lowered, while the lamp power rate of the third heating zone Z₃ is heightened. Meanwhile, the ARC lamp power rate is a parameter that determines the temperature of a wafer on which an atomic layer is to be deposited. The ARC lamp is set at a temperature as high as to heat up the wafer and deposit an atomic layer.

The rotary plate 45 is provided with a wafer groove 45a on its upper surface for placing the wafer 46 thereon. The wafer groove 45a prevents the atomic layer from being deposited on the bottom surface of the wafer 46 and protects the wafer 46 from being shaken while the rotary plate 45 is rotated.

In the ALD apparatus having the above-described structure, the source, reaction and purge gases are supplied through the central part (i.e., cone-shaped showerhead) of the top plate 41a. The supplied gases form a traveling wave-type of a flow towards the outside of the rotary plate 45, and then they are pumped into the outside of the reaction chamber. 40 through the discharging outlet 47 in the outside of the rotary plate 45.

The rotary plate 45 is rotated to secure a deposition uniformity and to place the wafer. Under the rotary plate 45, an inert gas, such as Ar, is flown to prevent an atomic layer from being deposited on the bottom surface of the rotary plate 45. The inert gas flowing on the bottom surface the rotary plate 45 is supplied from outside through an additional gas injection passage (not shown).

As described above, in the second embodiment of the present invention, gases are supplied from the central part of the reaction chamber 40 through the cone-shaped showerhead 42, and a plurality of wafers 46 are mounted on the rotary plate 45. The sheet resistance uniformity can be secured by dividing the heating zone into three, Z₁, Z₂ and Z₃, and controlling the temperature of the wafer 46 on which the atomic layer is to be deposited.

Meanwhile, the heating plate 43 having an array of loop-type ARC lamps 43a controls the heating power rate of each heating zone to have different temperatures, instead of maintaining a uniform temperature all around the entire region of the wafer 46.

FIG. 7 is a diagram showing the deposition status of an atomic layer, when it is deposited using the ALD apparatus of FIG. 6. Referring to FIG. 7, when the gas is injected to the chamber, the gas passes through the cone-shaped showerhead 42, whose exit is bigger than the entrance. Therefore, more gas atoms come to collide to the wafer 46, making the purging process more effective.

That is, the cone-shaped showerhead 42 has a gas injection hole and a gas ejection hole, and since the gas ejection hole is widened at a predetermined angle ▾, more gas atoms come to collide to the rotary plate 45 right under the gas ejection hole than the wafer 46. Since the margin of the gas flow-becomes wide, as it goes to the area close to the wafer 46, the remaining gas and the reaction by-products can be purged sufficiently to the outskirts of the rotary plate 45.

If the space (d) between the top plate 41a and the rotary plate 45 becomes wider, the purging effect is enhanced much more. In other words, when the space (d) is narrow, the gas remains more and more by-products are produced, as it goes to the third heating zone Z₃, thus interrupting the gas flow, and causing the re-deposition of the remaining gases in the third heating zone Z₃. However, if the space (d) is wide, the gas flows smoothly so that the remaining gas and by-products can be purged sufficiently, thus preventing the re-deposition of the remaining gases.

The deposition of the atomic layer on the top plate 41a can be prevented by forming a cooling plate 48 on the outside of the top plate 41a of the reaction chamber 41a. Here, the cooling plate 48 should be maintained at a temperature, for example, 200˜230 C, lower than the temperature that ALD is performed.

If the atomic layer deposition on the top plate 41a of a reaction chamber is prevented, the generation of the byproduct can be suppressed as well, so the purging effect becomes enhanced.

Meanwhile, the gas ejection hole of the cone-shaped showerhead 42 maintains the angle of 140˜160. If it is narrower than 140, the purging effect is deteriorated, and if it is wider than 160, the atomic layer deposited on the wafer has a poor thickness uniformity. For example, if the angle of the gas ejection hole is wider than 160, the atomic layer is likely to be deposited on the area further apart from the outskirts of the wafer 46 neighboring the cone-shaped showerhead 42. Therefore, the central area of the wafer 46 will be thinner than the outskirt area.

The space (d) between the cone-shaped showerhead 42 and the rotary plate 45 is maintained to be 3.5˜7 mm. If the space is smaller than 3.5 mm, the purging effect is degraded, and if the space is larger than 7 mm, the atomic layer is deposited unstably. Accordingly, the sheet resistance uniformity becomes poor.

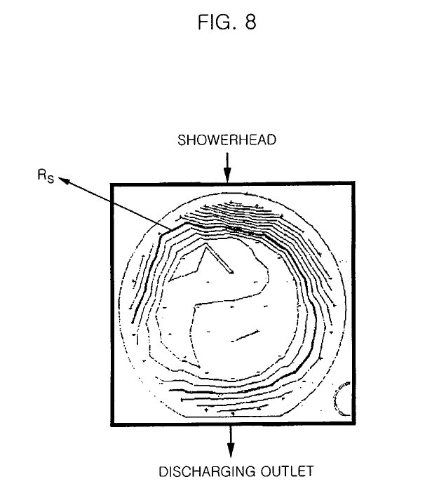

FIG. 8 is a map illustrating the sheet resistance uniformity after TiN is deposited using a reaction chamber of FIG. 6. To deposit TiN, 50 sccm of TiCl₄, a source gas, is supplied to the reaction chamber for 1.2 seconds under the chamber pressure of 3 torr. Subsequently, as a reaction gas, 1200 sccm of NH₃ is flown thereto for 1.2 seconds, and then as a purge gas, 800 sccm of Ar, is flown for 1.2 seconds. On the bottom surface of the wafer stage, 3000 sccm of Ar is flown to the reaction chamber for 1.2 seconds.

The space between the showerhead and the wafer stage is maintained to be 5 mm, and the wafer stage is rotated at a speed of 5 rpm. The heating unit is set at 480 C. The temperature of the wafer is maintained at 480 C by setting the ARC lamp power rate of the first heating zone Z₁ at 55%, the ARC lamp power rate of the second heating zone Z₂ at 65%, and the ARC lamp power rate of the third heating zone Z₃ at 95%. The cooling plate is maintained at 200˜230 C. The gas ejection hole of the showerhead has an angle of 160, and the diameter of the gas injection hole is 1.0 cm.

When TiN is deposited under the above-described conditions, the average sheet resistance is 72.9 2.99 ▾/sq, and the sheet resistance uniformity is measured to be 3.7%, as shown in FIG. 8. Particularly, the sheet resistance of the third heating zone Z₃ is close to the average sheet resistance, because Cl is removed due to the increased power rate of the third heating zone Z₃.

Differently from the first embodiment, the second embodiment of the present invention uses a cone-shaped showerhead, and the space between the showerhead and the rotary plate is wide. Also, the sheet resistance uniformity is reduced remarkably by lowering the power rate of the first heating zone Z₁ and heightening that of the third Z₃.

The atomic layers that can be deposited in the first and second embodiments of the present invention are nitrides, such as TiN, SiN, NbN, ZrN, TiN, TaN, Ya₃N₅, AlN, GaN, WN, BN, WBN, WSiN, TiSiN, TaSiN, AlSiN and AlTiN. Besides, a metal oxide and metallic thin film can be deposited as well. The metal oxide that can be deposited are any one selected from a group consisting of Al₂O₃, TiO₂, HfO₂, Ta₂O₅, Nb₂O₅, CeO₂, Y₂O₃, SiO₂, In₂O₃, RuO₂, IrO₂, SrTiO₃, PbTiO₃, SrRuO₃, CaRuO₃, (Ba,Sr)TiO₃, Pb(Zr,Ti)O₃, (Pb,La) (Zr,Ti)O₃, (Sr,Ca)RuO₃, and (Ba,Sr)RuO₃. The metallic thin film that can be deposited is any one selected from a group consisting of Al, Cu, Ti, Ta, Mo, Pt, Ru, Ir, W and Ag.

Meanwhile, the above-mentioned nitrides, metal oxides and metallic thin films are used for gate oxide layers, gate electrodes, top/bottom electrode of a capacitor, dielectric layer of a capacitor, barrier layer and metal wiring in the process of fabricating semiconductor devices. So, the batch-type ALD apparatus has a wide range of application.

In addition, since the ALD apparatus of the present invention has a large-volume reaction chamber that can contain four 200 mm wafers, the process conditions of 200 mm wafers can be applied to a case where 300 mm wafer is used. For example, if 300 mm wafer should be used, three wafers could be mounted on one chamber.

As described above, the ALD apparatus of the present invention produces an atomic layer with an improved sheet resistance uniformity by dividing the heating zone into three, and controlling the heating power rate of each heating zone. Since it can have four wafers per a batch, it can secure fine throughput and it can be used for mass-production.

While the present invention has been described with respect to certain preferred embodiments, it will be apparent to those skilled in the art that various changes and modifications may be made without departing from the scope of the invention as defined in the following claims.

What is claimed is:

1. An apparatus for depositing an atomic layer, comprising:
a chamber having a top plate, a bottom plate and a side wall;
a rotary plate in the chamber, wherein a plurality of wafers positioned on the rotary plate to equal distances from the center of the rotary plate;
a gas injecting means confronting the upper surface of the rotary plate at the center; and
a heating plate cable of controlling the temperature of the wafers according to the location, wherein the heating plate is mounted on the bottom plate and a space is provided between the heating plate and the bottom surface of the rotary plate.

2. The apparatus as recited in claim 1, wherein the gas injecting means is a radial-shaped showerhead.

3. The apparatus as recited in claim 2, wherein the gas injecting means penetrates the center of the top plate.

4. The apparatus as recited in claim 1, further comprising:
a rotary shaft which penetrates the center of the heating plate and bottom plate, and connects to the center of the bottom surface of the rotary plate; and
a gas outlet for discharging gases, wherein the gas outlet penetrates the bottom plate along the side wall of the chamber.

5. The apparatus as recited in claim 1, wherein the heating plate includes:
a first heating zone confronting the center of the bottom surface of the rotary plate;
a third heating zone aligned to the outskirts of the bottom surface of the rotary plate; and
a second heating zone between the first heating zone and the third heating zone.

6. The apparatus as recited in claim 5, wherein the second heating zone has a heating power rate higher than the first heating zone and lower than the third heating zone, and when the heating power rate of the second heating zone is fixed, if the heating power rate of the first heating zone is decreased, the heating power rate of the third heating zone is increased.

7. The apparatus as recited in claim 5, wherein the first, second and third heating zones are combinations of ARC lamps.

8. The apparatus as recited in claim 7, wherein the first heating zone is formed of three ARC lamps, and the second heating zone is formed of two ARC lamps, while the third heating zone includes one ARC lamp.

9. The apparatus as recited in claim 1, further comprising a cooling plate mounted on the upper surface of the top plate.

10. The apparatus as recited in claim 9, wherein the cooling plate is maintained at a temperature of 200˜230 C.

11. The apparatus as recited in claim 2, wherein the radial-shaped showerhead has a gas injection hole and a gas ejection hole, and the diameter of the gas ejection hole becomes large gradually from the part where the gas ejection hole contacts the gas injection hole, the gas ejection hole penetrating the top plate only.

12. The apparatus as recited in claim 11, wherein the bottom surface of the top plate and the gas ejection hole forms an angle of 140˜170.

13. The apparatus as recited in claim 9, wherein the top plate and the rotary plate are apart with a space of 3.5˜7 mm in-between.
